(19) United States
(12) Patent Application Publication
(10) Pub. No.: US 2025/0254949 A1
(43) Pub. Date: Aug. 7, 2025

(54) Trench Gate Semiconductor Device

(71) Applicant: Hangzhou Silicon-Magic Semiconductor Technology Co.,Ltd, Hangzhou (CN)

(72) Inventors: Hongyi XU, Hangzhou (CN); Jiakun WANG, Hangzhou (CN)

(73) Assignee: Hangzhou Silicon-Magic Semiconductor Technology Co.,Ltd, Hangzhou (CN)

(21) Appl. No.: 19/033,515

(22) Filed: Jan. 22, 2025

(30) Foreign Application Priority Data
Feb. 1, 2024 (CN) 2024101466375
Mar. 29, 2024 (CN) 2024103810729

(51) Int. Cl. H10D 62/17; H10D 30/66; H10D 62/10

(52) U.S. Cl. CPC H10D 62/393; H10D 30/668; H10D 62/127

(57) ABSTRACT

A semiconductor device having a first epitaxial layer of a first doping type, a second epitaxial of a second doping type and a third epitaxial layer of the first doping type. A first trench and a second trench vertically extend from a first surface of the third epitaxial layer into the third epitaxial layer. A body region of the second doping type arranged in the third epitaxial layer. A body contact region of the second doping type surrounding the body region. A buried region of the second doping type connecting a portion of the body region between the first trench and the second trench to the body contact region.

### CROSS-REFERENCE TO RELATED APPLICATION

This application claims the benefit of Chinese patent application No. 202410146637.5, filed on Feb. 1, 2024, and Chinese patent application No. 202410381072.9, filed on Mar. 29, 2024, which are incorporated herein by reference in its entirety.

### TECHNICAL FIELD

The present disclosure relates to semiconductor device structures and in particular to trench gate MOSFET.

### BACKGROUND

Silicon carbide trench gate MOSFET devices have the advantages of high input impedance, low driving current, high switching speed, and good high temperature characteristics, such that are widely used in electronic field.

With the development of silicon carbide power device technology, high cell density is one of the important trends.

### SUMMARY

In order to improve the cell density of the power device, the present disclosure provides a semiconductor device with a body contact region surrounding a transistor cell and a buried region connecting a portion of the body region to the circumambient body contact region.

The embodiments of the present invention are directed to a semiconductor device including a first epitaxial layer of a first doping type, a second epitaxial layer of a second doping type, a third epitaxial layer of the first doping type, a first trench, a second trench, a body region of the second doping type, the body contact region of the second doping type, and a buried region of the second doping type. The first trench and the second trench vertically extend from a first surface of the third epitaxial layer into the third epitaxial layer. The body region is arranged in the third epitaxial layer. The body contact region surrounds the body region. The buried region connects a portion of the body region between the first trench and the second trench to the body contact region.

The embodiments of the present invention are directed to a semiconductor device including a first epitaxial layer of a first doping type, a second epitaxial layer of a second doping type, a third epitaxial layer of the first doping type, a first trench, a second trench, a body region of the second doping type, a body contact region of the second doping type and a plurality of buried regions of the second doping type. The first trench and the second trench vertically extend from a first surface of the third epitaxial layer into the third epitaxial layer. The body region is arranged in the third epitaxial layer. The body contact region surrounds the body region. The plurality of buried regions connect a portion of the body region between the first trench and the second trench to the body contact region.

### BRIEF DESCRIPTION OF FIGURES

The present disclosure can be further understood with reference to following detailed description and appended drawings, wherein like elements are provided with like reference numerals. These drawings are only for illustration purpose, thus may only show part of the devices and are not necessarily drawn to scale. It is obvious that the drawings described below are some implementations of the present disclosure, and those skilled in the art would also obtain other drawings on the basis of these drawings, without involving any inventive skill.

FIG. 1 shows a top view of a transistor cell 10 of a power device in accordance with an embodiment of the present disclosure.

FIG. 2 shows a cross sectional view along A-A′ line of the transistor cell in FIG. 1 in accordance with an embodiment of the present disclosure.

FIG. 3 shows a cross sectional view along B-B′ line of the transistor cell in FIG. 1 in accordance with an embodiment of the present disclosure.

FIG. 4 shows a top view of a transistor cell 40 of a power device in accordance with an embodiment of the present disclosure.

FIG. 5 shows a cross sectional view along A-A′ line of the transistor cell 40 in FIG. 4 in accordance with an embodiment of the present disclosure.

FIG. 6 shows a top view of a transistor cell 60 of a power device in accordance with an embodiment of the present disclosure.

The use of the same reference label in different drawings indicates the same or like components.

### DETAILED DESCRIPTION

Various embodiments of the present disclosure will now be described. In the following description, some specific details, such as example circuits and example values for these circuit components, are included to provide a thorough understanding of embodiments. One skilled in the relevant art will recognize, however, that the present disclosure can be practiced without one or more specific details, or with other methods, components, materials, etc. In other instances, well-known structures, materials, processes or operations are not shown or described in detail to avoid obscuring aspects of the present disclosure.

Throughout the specification and claims, the terms “left”, “right”, “in”, “out”, “front”, “back”, “up”, “down”, “top”, “atop”, “bottom”, “on”, “over”, “under”, “above”, “below”, “vertical” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The phrases “in one embodiment”, “in some embodiments”, “in one implementation”, and “in some implementations” as used includes both combinations and sub-combinations of various features described herein as well as variations and modifications thereof. These phrases used herein does not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

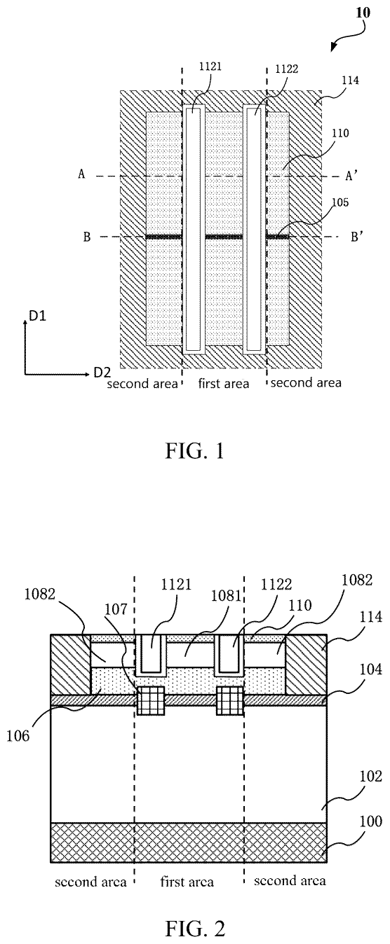

FIG. 1 shows a top view of a transistor cell 10 of a power device in accordance with an embodiment of the present disclosure.

The power device may be a SiC (Silicon Carbide) trench gate MOSFET device. As shown in FIG. 1, the transistor cell 10 includes a first trench 1121, a second trench 1122, a source region 110 and a body contact region 114. The first trench 1121 and the second trench 1122 extend parallelly along a first direction D1, and are spaced from each other in a second direction D2. The source region 110 adjoins sidewalls of the first trench 1121 and the second trench 1122. Beneath the source region 110, there is a body region which is not shown in the top view of the transistor cell 10 in FIG. 1. The body contact region 114 surrounds the source region 110 in the top view and meanwhile surrounds the body region. In the top view as shown in FIG. 1, the body contact region 114 forms a rectangle, and has two sides parallel with the first trench 1121 and the second trench 1122 in the first direction D1, and other two side normal to the first trench 1121 and the second trench 1122 in the second direction D2.

In the embodiment of FIG. 1, the transistor cell 10 has a first area and second areas on both sides of the first area. The first area refers to the area between the first trench 1121 and the second trench 1122, and the second area refers to the rest.

As shown in FIG. 1, the transistor cell 10 includes a buried region 105, having a strip structure. The buried region 105 extends along the second direction D2, which is normal to the length direction of the first trench 1121 and the second trench 1122. The width of the buried region 105 in the first direction D1 is much lesser than the length of the trench 1121 or 1122 in the first direction D1. In one embodiment, a ratio of the length of the trenches 1121 and 1122 in the first direction D1 to the width of the buried region 105 in the first direction D1 is less than or equal to 100:1. In one embodiment, the buried region 105 is located in the middle of the transistor cell 10 in the first direction D1, which means the buried region 105 has same distances to the opposite sides of the body contact region 114 in the first direction D1.

As shown in FIG. 1, the body contact region 114 is positioned at the edges of the transistor cell 10, which provides more room for accommodating trenches in the transistor cell 10, such that the current channels in a transistor cell are increased. Meanwhile, the on-resistance of the transistor cell is decreased, and extra resistance resulting from short space between the trench 1121/1122 and the body contact region 114 could be avoided. In the embodiment of FIG. 1, the body region (under the source region 110, and is not shown in the top view) in the first area, which is between the first trench 1121 and the second trench 1122, is connects to the body contact region 114 by two ends along the first direction D1 contacting the sides of the body contact region 114 which extends along the second direction D2, i.e., upper side and bottom side of the body contact region 114 as shown in FIG. 1. Since the body region along the first direction D1 is long, and the doping concentration of the body region is low compared with the body contact region 114, the potential of the middle region of the body region may be different from that close to the body contact region 114. Consequently, the stability of the power device may be affected.

In the embodiments of the present disclosure, transistor cell with two trenches is shown for example. In the second direction D2, the buried region 105 extends to and contacts the sides of the body contact region 114 which extend along the first direction D1. As a result, the potential of the middle part of the body region between the trenches, i.e., in the first area, is fixed to potential of the body contact region 114 by the buried region 105, solving the floating potential problem of the middle part of the body region which is far away from the body contact region sides at the ends the trenches 1121 and 1122. Accordingly, the stability of the threshold voltage and on-resistance of the power device is improved. Both of the body contact region 114 and the buried region 105 are of the same doping type and have a high doping concentration. In one embodiment, the body contact region 114 and buried region 105 may be P-type.

FIG. 2 shows a cross sectional view along A-A′ line of the transistor cell in FIG. 1 in accordance with an embodiment of the present disclosure.

As shown in FIG. 2, the transistor cell of the power device includes a substrate 100, a first epitaxial layer 102 on the substrate 100, and a second epitaxial layer 104 on the first epitaxial layer 102. Both of the substrate 100 and the first epitaxial layer 102 are of the same doping type, e.g., a first doping type. In one embodiment, the substrate 100 is of a n-type with a high doping concentration, and the first epitaxial layer 102, adopted as a drift region of the transistor cell, is of the n-type with a low doping concentration. The second epitaxial layer 104 is of a second doping type. In the second epitaxial layer 104, at least one electric channel region 107 of the first doping type is set.

The transistor cell 10 further includes a third epitaxial layer 106 on the second epitaxial layer 104. As shown in FIG. 2, the transistor cell 10 is divided into the first area, and the second areas. The first area refers to the area between the first trench 1121 and the second trench 1122. The second area refers to the area adjoins the first area. The first trench 1121 and the second trench 1122 extend vertically from a top surface of the transistor cell into the third epitaxial layer 106. The first trench 1121 and the second trench 1122 are in the first area. The third epitaxial layer 106 is of the first doping type.

In one embodiment, the second epitaxial layer 104 is of p-type and has a low doping concentration. The second epitaxial layer 104 shields the electric field and protects the bottom of the trenches from breakdown.

In one embodiment, the electric channel region 107 is of n-type. The electric channel region 107 provides a current path to lower the on-resistance of the transistor cell. In one embodiment, the electric channel region 107 has a medium doping concentration which is lower than the doping concentration of the substrate 100, but higher than the doping concentration of the first epitaxial layer 102. In one embodiment, the doping concentration of the electric channel region 107 may be 2e17cm⁻³˜7e17cm⁻³.

In one embodiment, the third epitaxial layer 106 is of n-type and is configured for decreasing the on-resistance of the transistor cell. In one embodiment, the third epitaxial layer 106 has a medium doping concentration which is lower than the doping concentration of the substrate 100, but is higher than the doping concentration of the first epitaxial layer 102. In one embodiment, the doping concentration of the third epitaxial layer 106 may be in a range of 3e16cm⁻³˜3e17cm⁻³.

In one embodiment, there is a distance from the top surface of the second epitaxial layer 104 to the bottoms of the first trench 1121 and the second trench 1122.

In one embodiment, the distance from the top surface of the second epitaxial layer 104 to the bottoms of the first trench 1121 is the same with the distance from the top surface of the second epitaxial layer 104 to the bottoms of the second trench 1122.

In one embodiment, the distance from the top surface of the second epitaxial layer 104 to the bottoms of the first trench 1121 is different from the distance from the top surface of the second epitaxial layer 104 to the bottoms of the second trench 1122.

The electric channel region 107 is positioned in the second epitaxial layer 104. A top surface of the electric channel region 107 is higher than a top surface of the second epitaxial layer 104, and a bottom surface of the electric channel region 107 is lower than a bottom surface of the second epitaxial layer 104, which makes sure that the electric channel region 107 work properly.

In one embodiment, under each one of the first trench 1121 and the second trench 1122, the electric channel region 107 could be embedded. A width of the electric channel region 107 is no larger than a width of the associated one of the first trench 1121 and the second trench 1122. In one embodiment, the electric channel region 107 has a width same with the width of the associated one of the first trench 1121 and the second trench 1122.

The on resistance of the transistor cell 10 increases as the distance between the electric channel region 107 and the bottom of the associated one of the first trench 1121 and the second trench 1122 increases. However, if the distance between the electric channel region 107 and the bottom of the associated one of the first trench 1121 and the second trench 1122 is too short, the on-resistance is also large due to the pinch-off effect. Moreover, a short distance may lead to an elevated risk of intensifying the electric field surrounding the trenches.

In one embodiment, the distance between the top of the electric channel region 107 and the bottom of the associated one of the first trench 1121 and the second trench 1122 is in a range of 0.1 μm-0.5 μm.

An ion implantation process is needed to form the electric channel regions 107. In some embodiments, the substrate and the epitaxial layers are made of SiC material, which has high hardness. The ion implantation process applied to the SiC material is hard to reach a 2 μm depth from a top surface of the transistor cell to form the electric channel regions 107. In one embodiment, the ion implantation process could be performed to form the electric channel regions 107 after forming the trenches 1121 and 1122.

In one embodiment, the second epitaxial layer 104 has a low doping concentration, and the electric channel region 107 has a medium doping concentration, which means that high-energy doping process could be omitted, and the problems stemmed from the high-energy doping process, like production capacity limitation and control challenge of line width, could be avoided. By configuring the electric channel region 107, the largest electric field is moved from the bottom corner of the trenches to the middle part of the bottom of the trenches. As a result, the reliability of the power device is enhanced. In other words, the power devices according to the embodiments of the present disclosure, have the advantages of low on resistance and high breakdown voltage.

The body region of the transistor cell 10 includes a first body region 1081 and second body regions 1082. The first body region 1081 is in the portion of the third epitaxial layer 106 that is in the first area. Specifically, the first body region 1081 is between the first trench 1121 and the second trench 1122. The first body region 1081 is of the second doping type. The body contact region 114 is in the third epitaxial layer 106 and is around transistor cell 10. The body contact region 114 has the second doping type. The second body regions 1082 are in the parts of the third epitaxial layer 106 which is in the second areas. Specifically, one of the second body regions 1082 is between the first trench 1121 and the one side of the circumambient body contact region 114, and the other one of the second body regions 1082 is between the second trench 1122 and another side of the circumambient body contact region 114. Source regions 110 are configured in the first body region 1181 and the second body regions 1182.

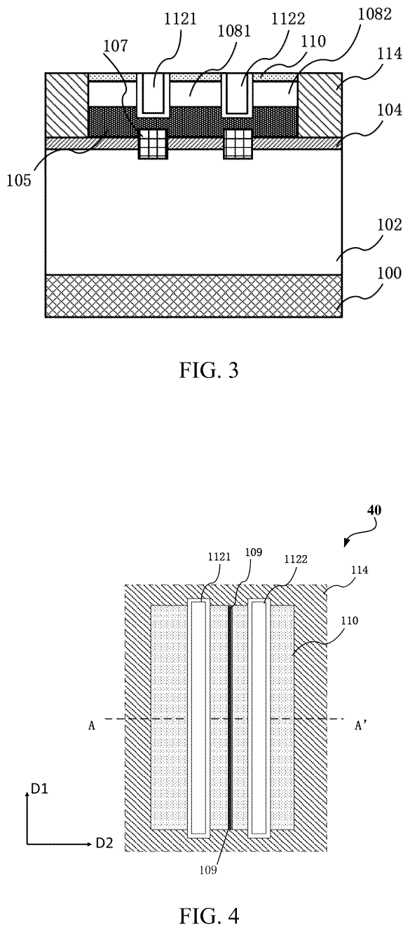

FIG. 3 shows a cross sectional view along B-B′ line of the transistor cell in FIG. 1 in accordance with an embodiment of the present disclosure.

Referring to FIGS. 1 and 3, the buried region 105 is arranged in the third epitaxial layer 106, for connecting the first body region 1081, the second epitaxial layer 104 and the body contact region 114. The buried region 105 is of the second doping type.

In one embodiment, the first body region 1081 and the second body regions 1082 are of p-type with a low doping concentration. The body contact region 114 is of p-type with a high doping concentration. The buried region 105 is of p-type with a high doping concentration.

In one embodiment, the lengths of the first trench 1121 and the second trench 1122 are extending along the first direction D1. The buried region 105 is in a strip structure and the length of the buried region 105 is extending along the second direction D2 which is normal to the first direction D1.

In one embodiment, the buried region 105 is arranged in the middle of the transistor cell 10 in the first direction D1, i.e., the buried region 105 have the same distances to the two opposite sides of the body contact region 114 in the first direction D1.

In the embodiments of the present disclosure, the body contact region 114 is positioned around the edge of the transistor cell 10, which save the room between the trenches. As a result, more trenches could be configured in the transistor cell such that the current channel density is increased and the on resistance of the power device is decreased.

The first body region 1081 between the first trench 1121 and the second trench 1122 contacts the body contact region 114 by the ends in the first direction D1. However, since the doping concentration of the body region 1081 is lower compared with the body contact region 114, the potential at portions of the body region 1081 distanced from the body contact region 114 differ from that near the body contact region 114, thus affecting the stability of power device during operation.

In the embodiments of the present disclosure, taking the transistor cell with two trenches as an example, by setting the buried region 105 as a strip structure in the second direction D2, and electrically connecting the ends of the strip buried region 105 to the circumambient body contact region 114, the potential floating problem in the body region 1081 between the first trench 1121 and the second trench 1122 due to its distance from the body contact region 114 is resolved, thereby improving the stability of the power device's threshold voltage and on-resistance. Both the body contact region 114 and the buried region 105 are of the second doping type and have a high doping concentration.

In one embodiment, when the electric channel regions 107 are positioned in the second epitaxial layer 104 directly under the first trench 1121 and the second trench 1122, the buried region 105 could connect the second epitaxial layer 104 to the ground potential, such that resolving the potential floating issue caused by the separation of the second epitaxial layer 104 due to the configuration of the electric channel regions 107, thus improving the stability of the power device's on resistance.

FIG. 4 shows a top view of a transistor cell 40 of a power device in accordance with an embodiment of the present disclosure.

The power device may be a SiC (Silicon Carbide) trench gate MOSFET device. As shown in FIG. 4, the transistor cell 40 of the power device includes the first trench 1121, the second trench 1122, the source region 110, the body contact region 114 and a buried region 109. The first trench 1121 and the second trench 1122 extend parallelly along a first direction D1, and are spaced away from each other in a second direction D2. The source region 110 adjoins sidewalls of the first trench 1121 and the second trench 1122. Beneath source region 110, there is a body region which is not shown in the top view of the power device in FIG. 4. The body contact region 114 surrounds the source region 110 in the top view and meanwhile adjoins the body region and the source region 110. The buried region 109 has a strip structure extending along the first direction D1. The strip buried region 109 is parallel with the first trench 1121 and the second trench 1122. In one embodiment, the buried region 109 is positioned between the first trench 1121 and the second trench 1122.

As shown in FIG. 4, the body contact region 114 has two sides arranged at the edges of the transistor cell 40, which are parallel to the trenches 1121 and 1122. The arrangement spares more rooms for trenches in the transistor cell, such that increases the current channel density and lowers the on resistance of the power device. In the embodiment of FIG. 4, in the first direction D1, the body region has two ends adjoining the body contact region 114. However, since the doping concentration of the body region is lower compared with the body contact region 114, the potential at portions of the body region distanced from the body contact region 114 differ from that near the body contact region 114, thus affecting the stability of power device during operation.

In the embodiments of the present disclosure, the transistor cell with two trenches is illustrated as an example. The buried region 109 is set in the first body region 1081 between the first trench 1121 and the second trench 1122, and has a strip shape in the first direction D1. The buried region 109 is distanced from the first trench 1121 and the second trench 1122, to avoid affecting the current channel at the sidewalls of the trenches. In one embodiment, the buried region 109 has equal distances to the first trench 1121 and the second trench 1122 in the second direction D2. The buried region 109 electrically connects to the circumambient body contact region 114 by the ends in the first direction D1, ensuring that each portion in the first body region 1081 along the first direction D1 is at the same potential as the body contact region 114, preventing potential floating. In the first direction D1, the ends of the buried region 109 are electrically connected to the body contact region 114 for grounding, thus addressing the issue of potential floating in the body region between trenches due to different distances of the body region portions from the body contact region 114, thereby improving the stability of the power device's threshold voltage and on resistance.

In one embodiment, both the body contact region 114 and the buried region 109 are of the second doping type with the high concentration. In one embodiment, the second doping type is p-type.

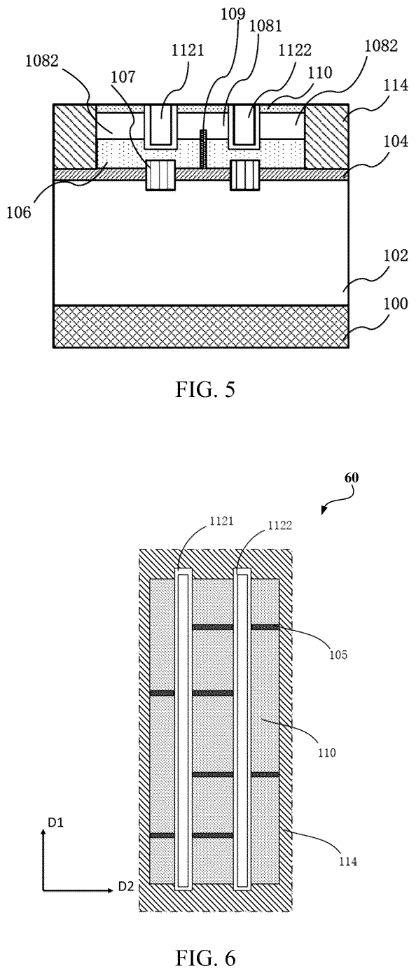

FIG. 5 shows a cross sectional view along A-A′ line of the transistor cell 40 in FIG. 4 in accordance with an embodiment of the present disclosure.

FIG. 6 shows a top view of a transistor cell 60 of a power device in accordance with an embodiment of the present disclosure.

As shown in the embodiment of FIG. 6, a plurality of buried regions 105 are configured. The plurality of buried regions 105 have lengths extending along the second direction D2. Some of the buried regions 105 connect to a side of the body contact region 114 near the first trench 1121, while some of the buried regions 105 connect to the opposite side of the body contact region 114 near the second trench 1122. Since the size of the buried regions 105 is small, the buried regions 105 has negligible impact on the current flow in the current channels along the trenches. Pinch-off resistance formed between each of the trenches 1121/1122 and the regions around the body contact region 114 negatively affects the conduction performance of the transistor cell. The first body region 1081, being distanced from the body contact region 114, may have its potential partially floating, which negatively impacts the conduction characteristics of the transistor cell. By adopting the plurality of buried regions 105, the different negative impacts to the different area separated by the electric channel regions could be mitigated, such that the conduction characteristics in different areas of the transistor cell could be improved.

While various embodiments have been described above to illustrate the semiconductor device and its manufacturing method of the present disclosure, it should be understood that they have been presented by way of example only, and not limitation. Rather, the scope of the present disclosure is defined by the following claims and includes combinations and sub-combinations of the various features described above, as well as variations and modifications thereof, which would occur to persons skilled in the art upon reading the foregoing description.

1. A semiconductor device, comprising:
a first epitaxial layer of a first doping type;
a second epitaxial layer of a second doping type;
a third epitaxial layer of the first doping type;
a first trench vertically extending from a first surface of the third epitaxial layer into the third epitaxial layer;
a second trench vertically extending from the first surface of the third epitaxial layer into the third epitaxial layer;
a body region of the second doping type arranged in the third epitaxial layer;
a body contact region of the second doping type surrounding the body region;
a buried region of the second doping type connecting a portion of the body region between the first trench and the second trench to the body contact region.

2. The semiconductor device of claim 1, wherein the buried region is beneath the body region and is of a strip shape with two ends contacting opposite sides of the body contact region respectively.

3. The semiconductor device of claim 2, wherein the buried region is normal to a length direction of the first trench and the second trench.

4. The semiconductor device of claim 3, wherein in the length direction of the first trench and the second trench, the buried region has same distances to the opposite sides of the body contact region.

5. The semiconductor device of claim 2, wherein the buried region is parallel to a length direction of the first trench and the second trench.

6. The semiconductor device of claim 5, wherein in a direction normal to the length direction of the first trench and the second trench, the buried region has same distances to the opposite sides of the body contact region.

7. The semiconductor device of claim 1, wherein the buried region and the body contact region have a higher doping concentration than the body region.

8. The semiconductor device of claim 1, further comprising a first electric channel region of the second doping type, extending from the third epitaxial layer, through the second epitaxial layer, to the first epitaxial layer, wherein the first electric channel region is under the first trench, and is positioned spaced from the first trench.

9. The semiconductor device of claim 8, wherein a width of the first electric channel region is smaller than a width of the first trench in a direction normal to a length direction of the first trench.

10. The semiconductor device of claim 8, wherein a distance from a top surface of the first electric channel region to a bottom of the first trench is in a range of 0.1 μm to 0.5 μm.

11. The semiconductor device of claim 8, further comprising a second electric channel region of the second doping type, extending from the third epitaxial layer, through the second epitaxial layer, to the first epitaxial layer, wherein the second electric channel region is under the second trench, and is positioned spaced from the second trench.

12. The semiconductor device of claim 11, wherein a width of the second electric channel region is smaller than a width of the second trench in a direction normal to a length direction of the second trench.

13. The semiconductor device of claim 11, wherein a distance from a top surface of the second electric channel region to a bottom of the second trench is in a range of 0.1 μm to 0.5 μm.

14. The semiconductor device of claim 8, wherein the first electric channel region and the second electric channel region have a higher doping concentration than the third epitaxial layer, and wherein the third epitaxial layer has a higher doping concentration than the first epitaxial layer.

15. A semiconductor device, comprising:
a first epitaxial layer of a first doping type;
a second epitaxial layer of a second doping type;
a third epitaxial layer of the first doping type;
a first trench vertically extending from a first surface of the third epitaxial layer into the third epitaxial layer;
a second trench vertically extending from the first surface of the third epitaxial layer into the third epitaxial layer;
a body region of the second doping type arranged in the third epitaxial layer;
a body contact region of the second doping type surrounding the body region;
a plurality of buried regions of the second doping type connecting a portion of the body region between the first trench and the second trench to the body contact region.

16. The semiconductor device of claim 15, wherein the plurality of buried regions are beneath the body region, and wherein each one of the plurality buried regions is of a strip shape with at least one end contacting a side of the body contact region.

17. The semiconductor device of claim 15, wherein a first portion of the plurality of buried regions connect the portion of the body region to a first side of the body contact region, and a second portion of the plurality of buried regions connect the portion of the body region to a second side of the body contact region, wherein the first side of the body contact region and the second side of the body region are opposite, and wherein the buried regions in the first portion of the buried regions are alternatively arranged with the buried regions in the second portion of the buried regions in a length direction of the first trench and the second trench.

18. The semiconductor device of claim 15, wherein the plurality of buried regions and the body contact region have a higher doping concentration than the body region.

19. The semiconductor device of claim 15, further comprising a first electric channel region of the second doping type under the first trench and a second electric channel region of the second doping type under the second trench, wherein the first electric channel region and the second electric channel region extend from the third epitaxial layer, through the second epitaxial layer, to the first epitaxial layer, and wherein the first electric channel region and the second electric channel region are positioned spaced from the first trench and the second trench respectively.

20. The semiconductor device of claim 19, wherein in a direction normal to a length direction of the first trench and the second trench, a width of the first electric channel region is smaller than a width of the first trench, and a width of the second electric channel region is smaller than a width of the second trench.
